(19) United States
(12) Patent Application Publication
(10) Pub. No.: US 2024/0069505 A1
(43) Pub. Date: Feb. 29, 2024

(54) SIMULATING AUTONOMOUS VEHICLE OPERATIONS AND OUTCOMES FOR TECHNICAL CHANGES

(71) Applicant: GM Cruise Holdings LLC, San Francisco, CA (US)

(72) Inventor: Lei Ma, Dublin, OH (US)

(21) Appl. No.: 17/900,225

(22) Filed: Aug. 31, 2022

(51) Int. Cl. G05D 1/02; G05B 17/02; G05D 1/00

(52) U.S. Cl. CPC G05D 1/0221; G05B 17/02; G05D 1/0088; G05D 2201/0213

(57) ABSTRACT

Systems and techniques are provided for simulating autonomous vehicle operations and outcomes for technical changes. An example method can include determining one or more conditions to be implemented in one or more autonomous vehicle (AV) driving simulations; simulating a performance of an autonomous vehicle with one or more AV modifications when driving in an environment having the one or more conditions; determining a particular impact that the one or more AV modifications need to have on the performance of the autonomous vehicle to achieve one or more objectives associated with the one or more conditions; and based on the particular impact that the one or more AV modifications need to have on the performance of the autonomous vehicle to achieve the one or more objectives, determining an AV modification estimated to have the particular impact on the performance of the autonomous vehicle needed to achieve the one or more objectives.

### TECHNICAL FIELD

The present disclosure generally relates to autonomous vehicles. For example, aspects of the present disclosure relate to techniques and systems for simulating autonomous vehicle operations and outcomes for certain technical changes.

### BACKGROUND

An autonomous vehicle is a motorized vehicle that can navigate without a human driver. An exemplary autonomous vehicle can include various sensors, such as a camera sensor, a light detection and ranging (LIDAR) sensor, and a radio detection and ranging (RADAR) sensor, amongst others. The sensors collect data and measurements that the autonomous vehicle can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system. Typically, the sensors are mounted at specific locations on the autonomous vehicles.

### BRIEF DESCRIPTION OF THE DRAWINGS

Illustrative embodiments of the present application are described in detail below with reference to the following figures:

FIG. 1 is a diagram illustrating an example system environment that can be used to facilitate autonomous vehicle navigation and routing operations, in accordance with some examples of the present disclosure;

FIG. 2A is a diagram illustrating an example flow for simulating an impact of one or more autonomous vehicle modifications on one or more objectives associated with an autonomous vehicle, in accordance with some examples of the present disclosure;

FIG. 2B is a diagram illustrating another example flow for simulating input objectives to determine one or more autonomous vehicle modifications that can allow an autonomous vehicle to meet the input objectives, in accordance with some examples of the present disclosure;

FIG. 3 is a diagram illustrating an example flow for determining civil planning recommendations based on autonomous vehicle simulations, in accordance with some examples of the present disclosure;

FIG. 4 is a flowchart illustrating an example process for simulating autonomous vehicle operations and outcomes for certain technical changes, in accordance with some examples of the present disclosure;

FIG. 5A is a flowchart illustrating an example process for simulating input objectives to determine one or more autonomous vehicle modifications that can allow an autonomous vehicle to meet an input objective, in accordance with some examples of the present disclosure;

FIG. 5B is a flowchart illustrating an example process for determining AV modifications that would satisfy one or more input objectives, in accordance with some examples of the present disclosure;

FIG. 6 is a diagram illustrating an example system architecture for implementing certain aspects described herein.

### DETAILED DESCRIPTION

Certain aspects and embodiments of this disclosure are provided below. Some of these aspects and embodiments may be applied independently and some of them may be applied in combination as would be apparent to those of skill in the art. In the following description, for the purposes of explanation, specific details are set forth in order to provide a thorough understanding of embodiments of the application. However, it will be apparent that various embodiments may be practiced without these specific details. The figures and description are not intended to be restrictive.

The ensuing description provides exemplary embodiments only, and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing from the scope of the application as set forth in the appended claims.

One aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

As previously explained, autonomous vehicles (AVs) can include various sensors, such as a camera sensor, a light detection and ranging (LIDAR) sensor, a radio detection and ranging (RADAR) sensor, amongst others, which the AVs can use to collect data and measurements that the AVs can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system.

Generally, autonomous vehicle companies perform various simulations to determine safety metrics of a particular autonomous vehicle(s) and determine any technology gaps or potential issues that may need to be addressed for optimal functioning of the autonomous vehicle. However, such simulations do not predict or determine the impact of certain autonomous vehicle operations and/or technologies on specific objectives or business outcomes. Described herein are systems, apparatuses, processes (also referred to as methods), and computer-readable media (collectively referred to as “systems and techniques”) for simulating autonomous vehicle operations and outcomes for certain technical changes. In some aspects, the systems and techniques described herein can simulate autonomous vehicle operations and business outcomes for certain technical changes. In some cases, the systems and techniques described herein can predict how to achieve a certain outcome, such as a business outcome or a specific objective, given a number of possible autonomous vehicle operations, technical capabilities, and/or technical changes.

In some examples, the systems and techniques described herein can estimate/forecast how a certain autonomous vehicle technology and/or technology improvement may affect commercial/business and/or operations metrics associated with the autonomous vehicle. For example, if one or more technologies of an autonomous vehicle are modified/updated to improve pedestrian detection in environments with a threshold amount of fog, the systems and techniques described herein can then determine one or more impacts to one or more business and/or operations factors/objectives.

To further illustrate, in the previous example, if one or more technologies of an autonomous vehicle are modified/updated to improve pedestrian detection in environments with a threshold amount of fog, the systems and techniques can then determine how much the speed of the autonomous vehicle can be increased in environments with the threshold amount of fog while maintaining specific safety metrics and operations costs associated with the autonomous vehicle. As another example, if one or more technologies of an autonomous vehicle are modified/updated to improve pedestrian detection in environments with a threshold amount of fog, the systems and techniques described herein can determine how much of an impact the modification/update to the one or more technologies of the autonomous vehicle may have on completing more trips and thus how much additional revenue may be generated by the modification/update to the one or more technologies of the autonomous vehicle.

Similarly, in some cases, the systems and techniques described herein can be used in “reverse” scenarios to determine what technological changes and/or updates can be implemented to achieve a certain objective and/or business outcome. For example, if the goal is to achieve a certain increase in revenue obtained from rides by an autonomous vehicle during days where the environment has a threshold amount of fog, the systems and techniques described herein can determine how much the autonomous vehicle's pedestrian detection capabilities (and/or any other detection capabilities) in environments with the threshold amount of fog need to be improved in order to achieve the certain increase in revenue from rides by the autonomous vehicle during days where the environment has the threshold amount of fog.

The systems and techniques described herein can extend simulations beyond simulating the autonomous vehicle software stack. In some examples, the systems and techniques described herein can incorporate big data from a history of past rides/deliveries by one or more autonomous vehicles, a history of past routes associated with the one or more autonomous vehicles, a history of a duration of each trip associated with the one or more autonomous vehicles, etc. In some cases, the systems and techniques described herein can use data relating to a company's order history to determine, for that company, how well a specific autonomous vehicle(s) may perform, an estimated revenue associated with trips by that autonomous vehicle(s), and/or operations costs associated with that autonomous vehicle(s).

For example, if Company Y provides a history of order information for a certain city over the course of n number of months in the last year, the systems and techniques described herein can ingest this order history information and show Company Y that during n number of months of this year, a specific autonomous vehicle(s) can deliver X amount of orders in less time or with less operational costs. Similarly, the systems and techniques described herein can determine that if an autonomous vehicle(s) is able to improve a routing efficiency by a certain amount, such improvement may decrease the average trip time of the autonomous vehicle(s) by a specific amount and/or can result in a certain increase in deliveries and/or revenue based on a list of orders (real or hypothetical).

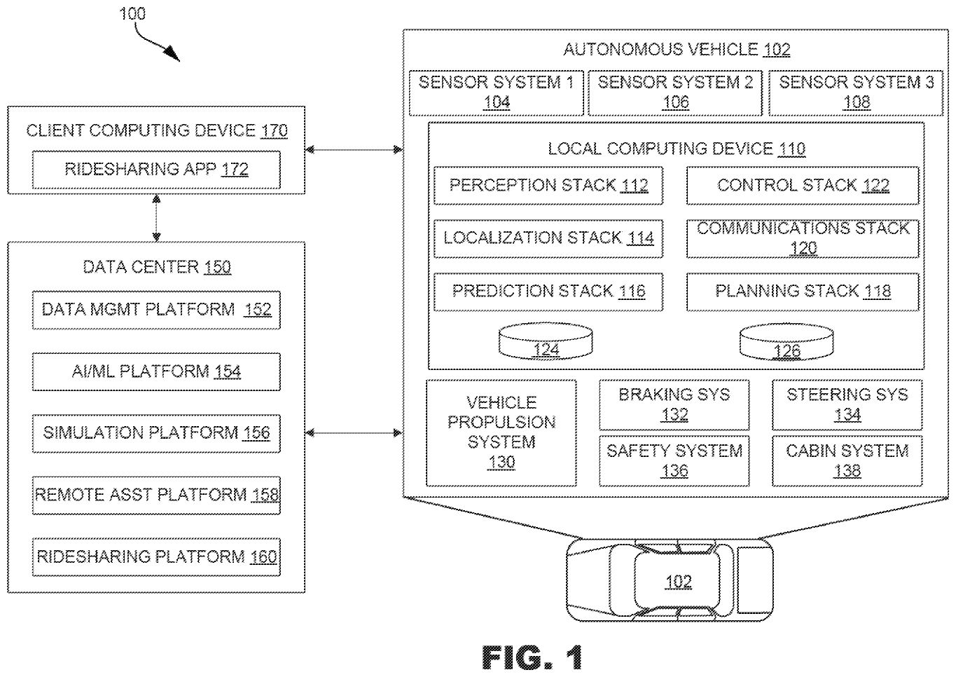

Examples of the systems and techniques described herein are illustrated in FIG. 1 through FIG. 6 and described below.

FIG. 1 is a diagram illustrating an example autonomous vehicle (AV) environment 100, according to some examples of the present disclosure. One of ordinary skill in the art will understand that, for the AV management system 100 and any system discussed in the present disclosure, there can be additional or fewer components in similar or alternative configurations. The illustrations and examples provided in the present disclosure are for conciseness and clarity. Other examples may include different numbers and/or types of elements, but one of ordinary skill the art will appreciate that such variations do not depart from the scope of the present disclosure.

In this example, the AV management system 100 includes an AV 102, a data center 150, and a client computing device 170. The AV 102, the data center 150, and the client computing device 170 can communicate with one another over one or more networks (not shown), such as a public network (e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

The AV 102 can navigate roadways without a human driver based on sensor signals generated by sensor systems 104, 106, and 108. The sensor systems 104-108 can include one or more types of sensors and can be arranged about the AV 102. For instance, the sensor systems 104-108 can include Inertial Measurement Units (IMUs), cameras (e.g., still image cameras, video cameras, etc.), light sensors (e.g., LIDAR systems, ambient light sensors, infrared sensors, etc.), RADAR systems, GPS receivers, audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 104 can be a camera system, the sensor system 106 can be a LIDAR system, and the sensor system 108 can be a RADAR system. Other examples may include any other number and type of sensors.

The AV 102 can also include several mechanical systems that can be used to maneuver or operate the AV 102. For instance, the mechanical systems can include a vehicle propulsion system 130, a braking system 132, a steering system 134, a safety system 136, and a cabin system 138, among other systems. The vehicle propulsion system 130 can include an electric motor, an internal combustion engine, or both. The braking system 132 can include an engine brake, brake pads, actuators, and/or any other suitable componentry configured to assist in decelerating the AV 102. The steering system 134 can include suitable componentry configured to control the direction of movement of the AV 102 during navigation. The safety system 136 can include lights and signal indicators, a parking brake, airbags, and so forth. The cabin system 138 can include cabin temperature control systems, in-cabin entertainment systems, and so forth. In some examples, the AV 102 might not include human driver actuators (e.g., steering wheel, handbrake, foot brake pedal, foot accelerator pedal, turn signal lever, window wipers, etc.) for controlling the AV 102. Instead, the cabin system 138 can include one or more client interfaces (e.g., Graphical User Interfaces (GUIs), Voice User Interfaces (VUIs), etc.) for controlling certain aspects of the mechanical systems 130-138.

The AV 102 can include a local computing device 110 that is in communication with the sensor systems 104-108, the mechanical systems 130-138, the data center 150, and/or the client computing device 170, among other systems. The local computing device 110 can include one or more processors and memory, including instructions that can be executed by the one or more processors. The instructions can make up one or more software stacks or components responsible for controlling the AV 102; communicating with the data center 150, the client computing device 170, and other systems; receiving inputs from riders, passengers, and other entities within the AV's environment; logging metrics collected by the sensor systems 104-108; and so forth. In this example, the local computing device 110 includes a perception stack 112, a mapping and localization stack 114, a prediction stack 116, a planning stack 118, a communications stack 120, a control stack 122, an AV operational database 124, and an HD geospatial database 126, among other stacks and systems.

The perception stack 112 can enable the AV 102 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 126, other components of the AV, and/or other data sources (e.g., the data center 150, the client computing device 170, third party data sources, etc.). The perception stack 112 can detect and classify objects and determine their current locations, speeds, directions, and the like. In addition, the perception stack 112 can determine the free space around the AV 102 (e.g., to maintain a safe distance from other objects, change lanes, park the AV, etc.). The perception stack 112 can identify environmental uncertainties, such as where to look for moving objects, flag areas that may be obscured or blocked from view, and so forth. In some examples, an output of the prediction stack can be a bounding area around a perceived object that can be associated with a semantic label that identifies the type of object that is within the bounding area, the kinematic of the object (information about its movement), a tracked path of the object, and a description of the pose of the object (its orientation or heading, etc.).

The mapping and localization stack 114 can determine the AV's position and orientation (pose) using different methods from multiple systems (e.g., GPS, IMUS, cameras, LIDAR, RADAR, ultrasonic sensors, the HD geospatial database 126, etc.). For example, in some cases, the AV 102 can compare sensor data captured in real-time by the sensor systems 104-108 to data in the HD geospatial database 126 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LIDAR). If the mapping and localization information from one system is unavailable, the AV 102 can use mapping and localization information from a redundant system and/or from remote data sources.

The prediction stack 116 can receive information from the localization stack 114 and objects identified by the perception stack 112 and predict a future path for the objects. In some examples, the prediction stack 116 can output several likely paths that an object is predicted to take along with a probability associated with each path. For each predicted path, the prediction stack 116 can also output a range of points along the path corresponding to a predicted location of the object along the path at future time intervals along with an expected error value for each of the points that indicates a probabilistic deviation from that point.

The planning stack 118 can determine how to maneuver or operate the AV 102 safely and efficiently in its environment. For example, the planning stack 118 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 102 from one point to another and outputs from the perception stack 112, localization stack 114, and prediction stack 116. The planning stack 118 can determine multiple sets of one or more mechanical operations that the AV 102 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 118 can select from multiple backup plans to carry out. For example, while preparing to change lanes to turn right at an intersection, another vehicle may aggressively cut into the destination lane, making the lane change unsafe. The planning stack 118 could have already determined an alternative plan for such an event. Upon its occurrence, it could help direct the AV 102 to go around the block instead of blocking a current lane while waiting for an opening to change lanes.

The control stack 122 can manage the operation of the vehicle propulsion system 130, the braking system 132, the steering system 134, the safety system 136, and the cabin system 138. The control stack 122 can receive sensor signals from the sensor systems 104-108 as well as communicate with other stacks or components of the local computing device 110 or a remote system (e.g., the data center 150) to effectuate operation of the AV 102. For example, the control stack 122 can implement the final path or actions from the multiple paths or actions provided by the planning stack 118. This can involve turning the routes and decisions from the planning stack 118 into commands for the actuators that control the AV's steering, throttle, brake, and drive unit.

The communications stack 120 can transmit and receive signals between the various stacks and other components of the AV 102 and between the AV 102, the data center 150, the client computing device 170, and other remote systems. The communications stack 120 can enable the local computing device 110 to exchange information remotely over a network, such as through an antenna array or interface that can provide a metropolitan WIFI network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communications stack 120 can also facilitate the local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 126 can store HD maps and related data of the streets upon which the AV 102 travels. In some examples, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include three-dimensional (3D) attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal u-turn lanes; permissive or protected only right turn lanes; etc.). The traffic controls lane can include geospatial information of traffic signal lights, traffic signs, and other road objects and related attributes.

The AV operational database 124 can store raw AV data generated by the sensor systems 104-108, stacks 112-122, and other components of the AV 102 and/or data received by the AV 102 from remote systems (e.g., the data center 150, the client computing device 170, etc.). In some examples, the raw AV data can include HD LIDAR point cloud data, image data, RADAR data, GPS data, and other sensor data that the data center 150 can use for creating or updating AV geospatial data or for creating simulations of situations encountered by AV 102 for future testing or training of various machine learning algorithms that are incorporated in the local computing device 110.

The data center 150 can include a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and/or any other network. The data center 150 can include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 can send and receive various signals to and from the AV 102 and the client computing device 170. These signals can include sensor data captured by the sensor systems 104-108, roadside assistance requests, software updates, ridesharing pick-up and drop-off instructions, and so forth. In this example, the data center 150 includes a data management platform 152, an Artificial Intelligence/Machine Learning (AI/ML) platform 154, a simulation platform 156, a remote assistance platform 158, and a ridesharing platform 160, among other systems.

The data management platform 152 can be a “big data” system capable of receiving and transmitting data at high velocities (e.g., near real-time or real-time), processing a large variety of data and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), and/or data having other characteristics. The various platforms and systems of the data center 150 can access data stored by the data management platform 152 to provide their respective services.

The AI/ML platform 154 can provide the infrastructure for training and evaluating machine learning algorithms for operating the AV 102, the simulation platform 156, the remote assistance platform 158, the ridesharing platform 160, and other platforms and systems. Using the AI/ML platform 154, data scientists can prepare data sets from the data management platform 152; select, design, and train machine learning models; evaluate, refine, and deploy the models; maintain, monitor, and retrain the models; and so on.

The simulation platform 156 can enable testing and validation of the algorithms, machine learning models, neural networks, and other development efforts for the AV 102, the remote assistance platform 158, the ridesharing platform 160, and other platforms and systems. The simulation platform 156 can replicate a variety of driving environments and/or reproduce real-world scenarios from data captured by the AV 102, including rendering geospatial information and road infrastructure (e.g., streets, lanes, crosswalks, traffic lights, stop signs, etc.) obtained from a cartography platform; modeling the behavior of other vehicles, bicycles, pedestrians, and other dynamic elements; simulating inclement weather conditions, different traffic scenarios; and so on.

The remote assistance platform 158 can generate and transmit instructions regarding the operation of the AV 102. For example, in response to an output of the AI/ML platform 154 or other system of the data center 150, the remote assistance platform 158 can prepare instructions for one or more stacks or other components of the AV 102.

The ridesharing platform 160 can interact with a customer of a ridesharing service via a ridesharing application 172 executing on the client computing device 170. The client computing device 170 can be any type of computing system such as, for example and without limitation, a server, desktop computer, laptop computer, tablet computer, smartphone, smart wearable device (e.g., smartwatch, smart eyeglasses or other Head-Mounted Display (HMD), smart ear pods, or other smart in-ear, on-ear, or over-ear device, etc.), gaming system, or any other computing device for accessing the ridesharing application 172. In some cases, the client computing device 170 can be a customer's mobile computing device or a computing device integrated with the AV 102 (e.g., the local computing device 110). The ridesharing platform 160 can receive requests to pick up or drop off from the ridesharing application 172 and dispatch the AV 102 for the trip.

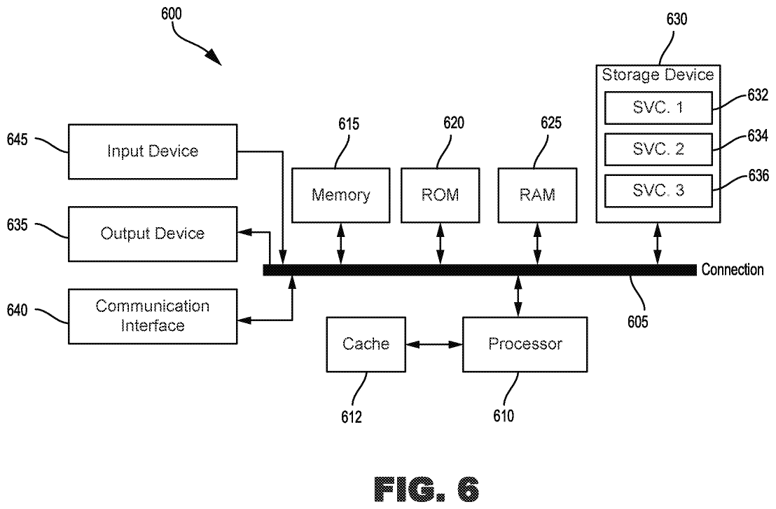

While the AV 102, the local computing device 110, and the autonomous vehicle environment 100 are shown to include certain systems and components, one of ordinary skill will appreciate that the AV 102, the local computing device 110, and/or the autonomous vehicle environment 100 can include more or fewer systems and/or components than those shown in FIG. 1. For example, the AV 102 can include other services than those shown in FIG. 1 and the local computing device 110 can also include, in some instances, one or more memory devices (e.g., RAM, ROM, cache, and/or the like), one or more network interfaces (e.g., wired and/or wireless communications interfaces and the like), and/or other hardware or processing devices that are not shown in FIG. 1. An illustrative example of a computing device and hardware components that can be implemented with the local computing device 110 is described below with respect to FIG. 6.

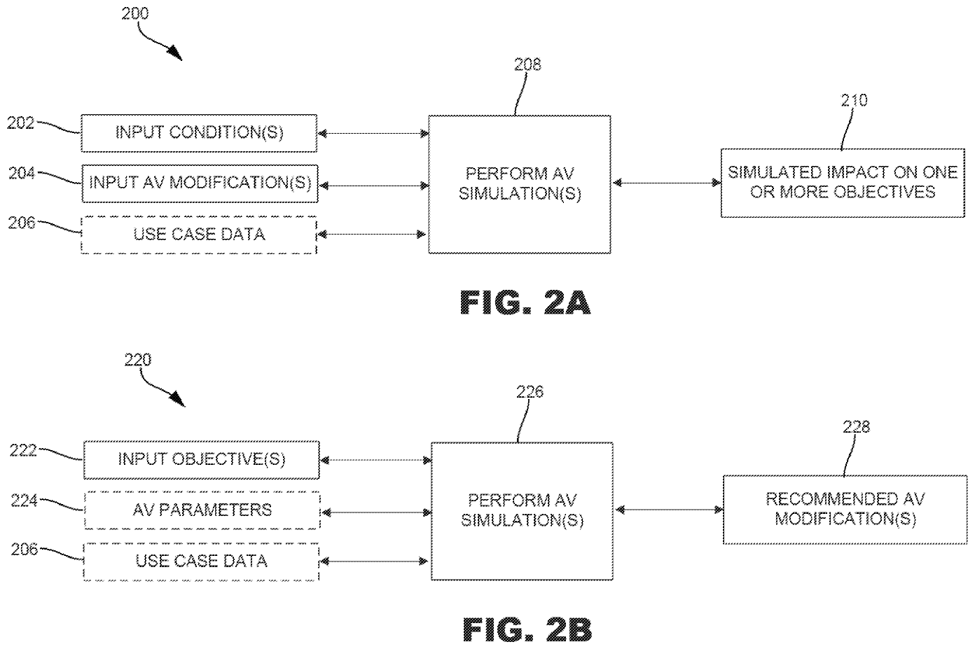

FIG. 2A is a diagram illustrating an example flow 200 for simulating an impact of one or more AV modifications on one or more objectives associated with an autonomous vehicle (e.g., AV 102). While the example flow 200 is described with respect to an impact of one or more AV modifications in the context of autonomous vehicles, the example flow 200 can be implemented in other contexts. For example, the example flow 200 can be implemented to simulate an impact of one or more modifications of an unmanned aerial vehicle, a train, a boat or ship, a subway vehicle, an airplane, a helicopter, an autonomous robotic machine, a roadway system for civil planning purposes, a warehouse configuration, etc.

In this example, the local computing device 110 (or any other computing device) can use an input condition(s) 202 and an input AV modification(s) 204 to perform an AV simulation(s) 208 to determine a simulated impact 210 on one or more objectives associated with an autonomous vehicle. For example, the local computing device 110 can simulate n number of trips by the autonomous vehicle in an environment(s) having the input condition(s) 202 to determine a simulated impact 210 of one or more AV modifications on the one or more objectives. By performing the AV simulation(s) 208, the local computing device 110 can determine the simulated impact 210 on one or more objectives of an AV modification(s) when the AV operates under the input condition(s) 202.

To illustrate, assume the input condition(s) 202 is a threshold amount of fog in an environment, the input AV modification(s) 204 is a new or modified sensor system and/or sensor data processing system for improved AV sensing/detection in environments with the threshold amount of fog condition, and the one or more objectives include a goal to decrease the time of trips by the autonomous vehicle in fog conditions and/or increase a number of trips completed by the autonomous vehicle in fog conditions (e.g., because of the improved AV sensing/detection). In this example, the AV simulation can simulate a number of trips performed by the autonomous vehicle in an environment(s) with the threshold amount of fog to determine an impact on the trip times and/or number of trips of the autonomous vehicle under the simulated fog conditions if the input AV modification(s) 204 is implemented on the autonomous vehicle (e.g., if the new or modified sensor system and/or sensor data processing system is/are implemented at the autonomous vehicle). In some cases, the local computing device 110 can perform the AV simulation(s) 208 without receiving the input AV modification(s) 204. Instead, the local computing device 110 can determine one or more AV modifications and use the determined one or more AV modifications to perform the AV simulation(s) 208 (in addition to the input condition(s) 202) and determine the simulated impact 210 on the one or more objectives. Alternatively, the local computing device 110 can arbitrarily or randomly select one or more AV modifications and use such one or more AV modifications to perform the AV simulation(s) 208 (in addition to the input condition(s) 202) and determine the simulated impact 210 on the one or more objectives.

The input condition(s) 202 can include, for example and without limitation, a weather condition (e.g., fog, rain, snow, ice, wind, precipitation, and/or any other weather condition), a condition of an environment (e.g., a traffic pattern and/or density, a road condition, a type of zone (e.g., construction zone, residential zone, industrial zone, etc.), a road closure, an object or obstruction along a route in the environment, a lighting condition (e.g., light, dark, etc.), a type of road associated with the environment, a visibility condition, animal crossings, etc.), a regulation associated with the environment (e.g., a speed limit, a permitted vehicle behavior/action, a prohibited vehicle behavior/action, etc.), and/or any other condition. Moreover, the input AV modification(s) 204 can include any modification to the autonomous vehicle.

For example, the input AV modification(s) 204 can include an upgrade or modification to one or more AV stacks (e.g., perception stack, control stack, localization stack, communications stack, prediction stack, planning stack, etc.); a replacement, upgrade, or modification of one or more mechanical systems of the autonomous vehicle; a replacement, upgrade, or modification of one or more hardware systems (e.g., a sensor system(s), an AV computing system, a lighting system, etc.); a replacement, upgrade, or modification of one or more components of the autonomous vehicle and/or a modification to a configuration of one or more components of the autonomous vehicle (e.g., a modification to a cabin of the autonomous vehicle, a modification to a container of the autonomous vehicle used to transport items, a change in the tires or type of tires of the autonomous vehicle, a change or modification of a vehicle frame, a change or modification of a braking system of the autonomous vehicle, a change or modification of a battery system of the autonomous vehicle, etc.); a change or modification to a body of the autonomous vehicle; a replacement of one or more vehicle parts (e.g., implementing better quality parts, implementing newer parts, etc.); a change to the vehicle model of the AV; and/or any change or modification to one or more components, technologies, and/or aspects of the autonomous vehicle.

The one or more objectives can include any type of objectives such as, for example and without limitation, a business objective (e.g., increased revenue generated by the autonomous vehicle through trips such as rides and/or deliveries), decreased costs of operating the autonomous vehicle for certain trips such as rides and/or deliveries, an increased number of trips that the autonomous vehicle can complete under certain conditions, a decreased time for the autonomous vehicle to complete trips under certain conditions, an increased number and/or type of environments and/or roads that the autonomous vehicle can traverse, an increased amount of passengers and/or goods that the autonomous vehicle can transport, an increased battery performance and/or efficiency, a reduced wear-and-tear of vehicle, an increase in the hours of operation of the autonomous vehicle, an increase in the service area and/or the map coverage of the service area, an increase in the number of operating environments, an increase in the number of orders delivered and/or completed by the autonomous vehicle, an ability to complete trips faster at night (e.g., because of improved capabilities for night driving such as improved lighting and/or sensing), an increased ability to detect things crossing the street (e.g., pedestrians, animals, objects, etc.), an increase in the mean time to failure of the AV or any sub-component or sub-system of the AV, a decrease in the amount of vehicle maintenance and operation support (e.g. servicing, cleaning, etc.) of the AV, etc.

For example, the one or more objectives can include an objective to increase the number of trips that the autonomous vehicle can complete under fog conditions (e.g., input condition(s) 202) and/or the time it takes the autonomous vehicle to complete each trip under fog conditions. In this example, the AV simulation can determine an impact on trips under fog conditions if the input AV modification(s) 204 is implemented on the autonomous vehicle. As another example, the one or more objectives can include an objective to increase the number of trips that the autonomous vehicle can complete in routes through a construction zone (e.g., input condition(s) 202) and/or the time it takes the autonomous vehicle to complete each trip through a route that includes a construction zone. In this example, the AV simulation can determine an impact on trips along routes that have construction zones if the input AV modification(s) 204 is implemented on the autonomous vehicle.

In some cases, to perform the AV simulation(s) 208, the local computing device 110 can also process input use case data 206. In some examples, the use case data 206 can include a history of real and/or simulated trips (and/or metrics thereof) by the autonomous vehicle (or additionally or alternatively by other autonomous vehicles). The local computing device 110 can use the use case data 206 to simulate the impact of the input condition(s) 202 and input AV modification(s) 204 on the one or more objectives. The use case data 206 can provide metrics and/or historical trip data to help the local computing device 110 determine a performance of the autonomous vehicle given the input condition(s) 202 and the input AV modification(s) 204.

For example, in some cases, the use case data 206 can include a history and/or metrics of real and/or simulated AV trips under fog conditions. In this example, if the input condition(s) 202 includes a fog condition, the local computing device 110 can use the use case data 206 to help simulate an impact of an input AV modification(s) 204 on one or more objectives given the input condition(s) 202 (e.g., the fog condition). Thus, if the one or more objectives include an objective to increase the number of AV trips completed under the fog condition (e.g., because of improved fog capabilities resulting from the input AV modification(s) 204) and/or decrease the AV trip time under fog conditions, the AV simulation(s) 208 can use the use case data 206, the input AV modification(s) 204, and the input condition(s) 202 to determine an impact of the input AV modification(s) 204 on the number of AV trips and/or AV trip times in fog conditions.

FIG. 2B is a diagram illustrating another example flow 220 for simulating input objectives to determine one or more AV modifications that can allow an autonomous vehicle (e.g., AV 102) to meet the input objectives. While the example flow 220 is described with respect to an autonomous vehicle, the example flow 220 can be implemented in other contexts. For example, the example flow 220 can be implemented to simulate input objectives to determine one or more modifications to an unmanned aerial vehicle, a train, a boat, a subway vehicle, an airplane, a helicopter, an autonomous robotic machine, a roadway system for civil planning purposes, a warehouse configuration, etc.

In this example, the local computing device 110 (or any other computing device) can use an input objective(s) 222 to perform an AV simulation(s) 226 to determine one or more recommended AV modifications 228 that will allow the autonomous vehicle to meet the input objective(s) 222. For example, if the input objective(s) 222 is to increase the revenue of ridesharing trips during rainy conditions (e.g., environments with at least a threshold amount of precipitation), the local computing device 110 can perform an AV simulation(s) 226 to determine one or more recommended AV modifications 228 that would allow the autonomous vehicle to increase the revenue of ridesharing trips during rainy conditions (e.g., by increasing AV capabilities during rainy conditions and thus the autonomous vehicle's ability to complete more trips for more revenue during the rainy conditions and/or the autonomous vehicle's ability to reduce the duration of trips during rainy conditions). In this example, the recommended AV modifications 228 can include any modifications that may allow the autonomous vehicle to increase its performance during rainy conditions, decrease the amount of time per trip during rainy conditions, increase the number of trips completed during rainy conditions, etc. To illustrate, the recommended AV modifications 228 can include, for example and without limitation, a change of tires to implement tires that perform better in the rain, a change in one or more sensors that allows the autonomous vehicle to better perceive it's environment during rainy conditions, an implementation of a lighting system that increases a visibility during rainy conditions, and/or any other modification that would directly or indirectly result in increased revenue from ridesharing trips during rainy conditions.

As another example, if the input objective(s) 222 is to increase the revenue from trips for delivering goods, the local computing device 110 can perform an AV simulation(s) 226 to determine one or more recommended AV modifications 228 that would allow the autonomous vehicle to increase the revenue of trips for delivering goods. In this example, the recommended AV modifications 228 can include any modifications that may allow the autonomous vehicle to increase the amount of goods it can deliver per trip, decrease the amount of time per trip, increase the number of trips completed during a period of time, etc. To illustrate, the recommended AV modifications 228 can include, for example and without limitation, a bigger basket or container used to carry goods for delivery such that the bigger basket or container can carry more goods per trip, a modification to the planning stack that may allow the autonomous vehicle to complete more trips during a period of time, an update to one or more sensor systems that may allow the autonomous vehicle to improve its perception abilities and thus increase its performance and reduce its completion times for delivery trips, etc.

The input objective(s) 222 can include any type of objective such as, for example and without limitation, a business objective (e.g., increased revenue generated by the autonomous vehicle through trips such as rides and/or deliveries, decreased costs of operating the autonomous vehicle for certain trips such as rides and/or deliveries, increased number of trips that the autonomous vehicle can complete under certain conditions, decreased time for the autonomous vehicle to complete trips under certain conditions, increased number and/or type of environments and/or roads that the autonomous vehicle can traverse, increased amount of passengers and/or goods that the autonomous vehicle can transport, increased battery performance and/or efficiency, reduced wear-and-tear of vehicle, etc.

The recommended AV modification(s) 228 determined by the AV simulation can include any modification to the autonomous vehicle. For example, the recommended AV modification(s) 228 can include an upgrade or modification to one or more AV stacks (e.g., perception stack, control stack, localization stack, communications stack, prediction stack, planning stack, etc.), an upgrade or modification to one or more mechanical systems of the autonomous vehicle, an implementation (e.g., an upgrade, a modification, or a new implementation) of one or more hardware systems (e.g., a sensor system(s), an AV computing system, a lighting system, etc.), a modification to one or more components of the autonomous vehicle and/or a configuration of one or more components of the autonomous vehicle (e.g., a modification to a cabin of the autonomous vehicle, a modification to a container of the autonomous vehicle used to transport items, a change in the tires or type of tires of the autonomous vehicle, a change or modification of a vehicle frame, a change or modification of a braking system of the autonomous vehicle, a change or modification of a battery system of the autonomous vehicle, etc.), a change or modification to a body of the autonomous vehicle, and/or any change or modification to one or more components, technologies, and/or aspects of the autonomous vehicle.

In some cases, the recommended AV modification(s) 228 can include one or more proposed improvements to the AV estimated to achieve a business/operational goal(s) within the limits of what is physically possible by physical components (e.g., hardware, mechanical systems, etc.) of the AV and/or any other limitations defined (e.g., implicitly and/or explicitly) for the AV. For example, LIDAR rays cannot exceed the speed of light so the speed of rays generated by any LIDARs on the AV is limited by the speed of light. As another example, the AV cannot go over the speed limit so the speed limit of a road traversed by the AV can be an implicitly-defined limitation. As yet another example, an engineer may set the maximum range of a LIDAR of the AV to 2000 meters (m). Thus, in this example, the 2000 m range of the LIDAR can be an example of an explicitly-defined limitation. In some cases, the local computing device 110 may perform the AV simulation(s) 226 and output a set of improvements across one or more stacks/systems of the AV. For example, the local computing device 110 can output several proposals/recommendations across one or more stacks/systems of the AV so users do not have to pick and choose what aspects of the AV they want or do not want to modify (e.g., improve) in order to fulfill a certain business/operational objective.

In some examples, to perform the AV simulation(s) 226 and generate a recommended AV modification(s) 228, the local computing device 110 can also process AV parameters 224 and/or use case data 206 (in addition to the input objective(s) 222). For example, the input to the AV simulation(s) 226 can include the input objective(s) 222 and optionally the AV parameters 224 and/or use case data 206. The local computing device 110 can then perform the AV simulation 226 and generate the recommend AV modification(s) 228, as previously explained.

The AV parameters 224 can help simulate a behavior(s) and/or performance of the autonomous vehicle as currently configured and/or simulate a behavior and/or performance of the autonomous vehicle given one or more modifications to the autonomous vehicle. In some cases, the AV parameters 224 can include a description of any technologies implemented by the autonomous vehicle, a description to any available upgrades/modifications to any technologies implemented by the autonomous vehicle, a description of any available technologies that can be added to or implemented by the autonomous vehicle, an upgrade/modification to one or more software components of the autonomous vehicle (e.g., routing stack, perception stack, control stack, localization stack, communications stack, prediction stack, planning stack, etc.), a description of configuration changes to the autonomous vehicle, a description of available changes to the autonomous vehicle, performance metrics associated with the autonomous vehicle, metrics (e.g., performance metrics, safety metrics, etc.) associated with one or more components and/or modifications to the autonomous vehicle, a description of new or modified components that can be implemented by the autonomous vehicle, and/or any other AV parameters.

The use case data 206 can include a history of real and/or simulated trips (and/or metrics thereof) by the autonomous vehicle (or additionally or alternatively by other autonomous vehicles). The local computing device 110 can use the use case data 206 to simulate the impact of one or more AV modifications in relation to the input objective(s) 222. The use case data 206 can provide metrics and/or historical trip data to help the local computing device 110 determine a performance of the autonomous vehicle given a current configuration of the autonomous vehicle and/or any AV modifications.

For example, in some cases, the use case data 206 can include a history and/or metrics of real and/or simulated AV trips through routes having a construction zone. In this example, if the input objective(s) 222 includes an objective to increase revenue by increasing a performance and/or enabling a capability of the autonomous vehicle to maneuver through construction zones (e.g., and thus decrease the trip times through construction zones and/or by using shorter/faster routes through construction zones), the local computing device 110 can use the use case data 206 to help simulate an impact of one or more AV modification(s) on the input objective(s) 222. Thus, if the input objective(s) 222 includes an objective to decrease trip times by using routes with construction zones and/or by reducing the time to traverse a construction zone, the AV simulation(s) 226 can use the use case data 206, the input objective(s) 222, and optionally the AV parameters 224 to simulate trips through construction zones and determine an impact of one or more AV modification(s) on the input objective(s) 222.

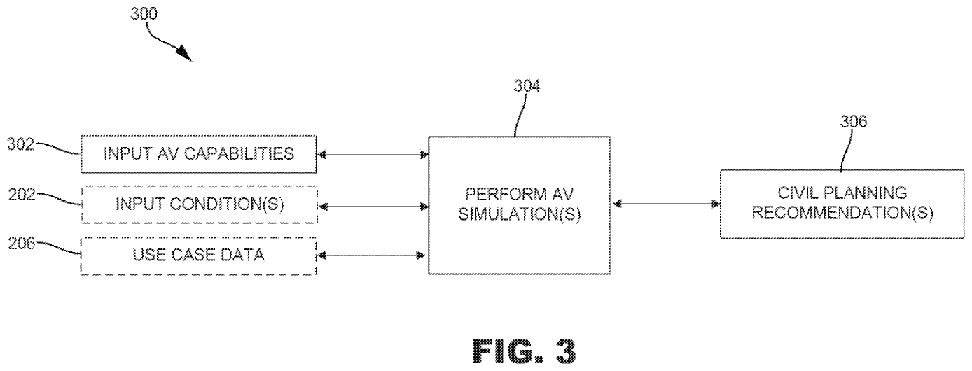

FIG. 3 is a diagram illustrating an example flow 300 for determining civil planning recommendations based on AV simulations. In this example, the flow 300 can obtain input AV capabilities 302 to perform an AV simulation(s) 304 that simulates a performance of one or more AVs in an environment(s). The AV simulation(s) 304 can be used to generate civil planning recommendation(s) 306 designed to achieve certain improvements and/or objectives based on the AV simulation(s) and the input AV capabilities. For example, the AV simulation(s) 304 can take into account the input AV capabilities 302 to determine the civil planning recommendation(s) 306 such that AV capabilities, AV simulated performance information and/or metrics, etc., are used to help with civil planning to ensure certain civil planning improvements and/or objectives are met given the AV capabilities, AV simulated performance information and/or metrics, etc.

In some examples, the civil planning recommendation(s) 306 can specify a recommended and/or optimal configuration of roadways (e.g., number of lanes, placement of traffic signs, number and/or configuration of curves and/or hills, number and/or placement of intersections, speed limits, emergency lanes, etc.), placement of resources along one or more routes (e.g., charging stations, gas stations, service stops, traffic signs, hospitals, airports, warehouses, parking lots/garages, speed/traffic cameras/sensors, road barriers and/or guardrails, train stations, bus stations, etc.), ingress and/or egress areas (e.g., number of ingress and/or egress roads for a region such as a city or neighborhood, configuration of ingress and/or egress roads, location of ingress and/or egress roads, etc.), placement of bridges (e.g., location of bridges, configuration of bridges, number of bridges, etc.), and/or any other civil planning recommendations.

In some cases, the input AV capabilities 302 can include AV capabilities of one or more autonomous vehicles expected to transit a relevant geographic area. In other cases, the input AV capabilities 302 can include a set of AV capabilities shared among all or a set of autonomous vehicles. In yet other cases, the input AV capabilities 302 can include a set of required AV capabilities by a specific regulatory body and/or an average set of capabilities determined from a number of available autonomous vehicles in the market. In some aspects, one or more users running the AV simulation(s) 304 and/or involved in the civil planning can define specific AV capabilities to include as the input AV capabilities 302.

In some examples, the AV simulation(s) 304 can further receive and process one or more input conditions 202 and/or use case data 206 as inputs to determine the civil planning recommendation(s) 306. For example, the one or more input conditions 202 can define certain weather conditions, environmental conditions, traffic conditions, landscape conditions, city planning conditions, traffic flow conditions, bottleneck conditions, and/or any other conditions, which the AV simulation(s) 304 can take into account when performing an AV simulation and/or generating a civil planning recommendation(s).

The use case data 206 can similarly help the AV simulation(s) 304 by providing real and/or simulated trip information to help generate AV simulations given the input AV capabilities 302. For example, in some cases, the use case data 206 can include a history and/or metrics of real and/or simulated AV trips through one or more routes and/or environments. The history and/or metrics of real and/or simulated AV trips can help perform AV simulations based on the input AV capabilities 302 and determine the civil planning recommendation(s) 306.

The example flow 300 was described above with respect to civil planning. However, in other examples, the AV simulation(s) 304 in the example flow 300 can be used to generate other types of recommendations. For example, in other cases, the AV simulation(s) 304 can be used to determine a placement and/or configuration of one or more buildings, resources, structures, etc., such as, for example and without limitation, warehouses, building plans, hospitals, airports, charging stations, gas stations, service areas, parking lots, emergency lanes/routes, delivery routes, ridesharing routes, ports, emergency personnel and/or equipment, garages, shopping areas, etc.

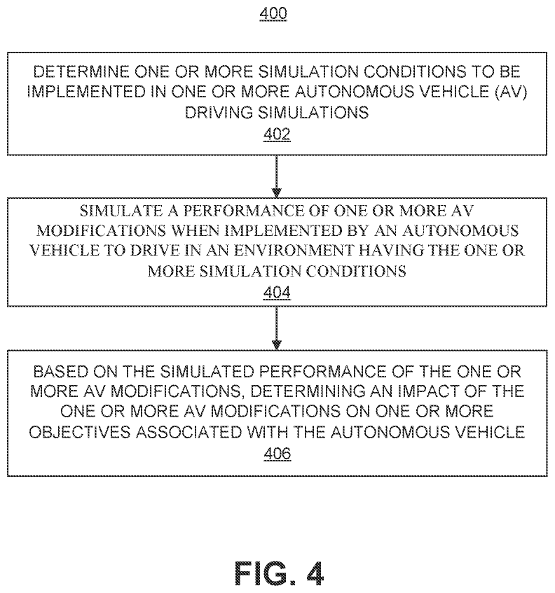

FIG. 4 is a flowchart illustrating an example process 400 for simulating an impact of one or more AV modifications on one or more objectives associated with an autonomous vehicle (e.g., AV 102). At block 402, the process 400 can include determining one or more simulation conditions to be implemented in one or more AV driving simulations. In some examples, the one or more simulation conditions can include a weather condition (e.g., snow, fog, wind, rain, ice, precipitation, etc.), an environment condition (e.g., construction, an obstruction, poor visibility, etc.), a traffic condition, a road condition (e.g., an accident, a road closure, an intersection, a road with a threshold amount and/or degree of curves and/or hills, a pothole, a malfunctioning traffic sign, etc.), a legal and/or regulatory condition (e.g., traffic laws and regulations, traffic signs/signals, local laws and regulations, etc.), and/or an event in the environment (e.g., a concert, a conference, an accident, a race, a festival, an emergency, etc.).

At block 404, the process 400 can include simulating a performance of one or more AV modifications when implemented by an autonomous vehicle to drive in an environment having the one or more simulation conditions. In some examples, the one or more AV modifications can include a modification or replacement of a software of the autonomous vehicle, a hardware component(s) of the autonomous vehicle, a mechanical system(s) of the autonomous vehicle, a part(s) of the autonomous vehicle, a vehicle model associated with the autonomous vehicle, a cabin of the autonomous vehicle, and/or a container used by the autonomous vehicle to transport one or more items. For example, the process 400 can simulate n number of trips by the autonomous vehicle with the one or more AV modifications in an environment having the one or more simulation conditions to determine a performance of the one or more AV modifications when used under the one or more simulation conditions.

In some cases, the process 400 can determine the one or more AV modifications and use the determined one or more AV modifications to perform the simulation and determine the simulated performance of the one or more AV modifications under the one or more simulation conditions. In some examples, the process 400 can arbitrarily or randomly select the one or more AV modifications and use such one or more AV modifications to perform the simulation and determine the performance of the one or more AV modifications under the one or more simulation conditions. In other cases, the process 400 can receive the one or more AV modifications as an input of modifications to simulate, and use the input one or more AV modifications to perform the simulation and determine the simulated performance of the input one or more AV modifications under the one or more simulation conditions.

At block 406, the process 400 can include determining, based on the simulated performance of the one or more AV modifications, an impact of the one or more AV modifications on one or more objectives associated with the autonomous vehicle. In some examples, the one or more objectives can include an increased number of trips that the autonomous vehicle can complete within a period of time under the one or more simulation conditions, a decreased amount of time the autonomous vehicle takes to complete one or more trips under the one or more simulation conditions, an increased amount of items that the autonomous vehicle can deliver under the one or more simulation conditions, an increased number of people that the autonomous vehicle can transport within a period of time and under the one or more simulation conditions, an increased battery performance or efficiency, an increased revenue from one or more paid trips by the autonomous vehicle under the one or more simulation conditions, an increase in the hours of operation of the autonomous vehicle, an increase in the service area and/or the map coverage of the service area, an increase in the number of operating environments, an increase in the number of orders delivered and/or completed by the autonomous vehicle, maximizing rider comfort for sleeping/working/traveling in the AV, minimizing car sickness of any passengers of the AV, minimizing perceived slowness of the AV (e.g., driving on the highway even if the distance is longer so the AV is perceived to travel faster), Sand/or any business objective.

In some aspects, the process 400 can include determining at least one objective associated with the autonomous vehicle, simulating a performance of at least one AV modification associated with the autonomous vehicle, and based on the simulated performance, determining a recommended AV modification(s) estimated to satisfy the at least one objective when implemented on the autonomous vehicle. In some examples, the process 400 can provide multiple recommendations to a user(s) of the AV. For example, the process 400 can generate a plurality or list of recommendations (e.g., multiple recommended AV modifications, etc.) to a user of the AV. In some cases, the user can select all or a subset of the recommendations provided by the process 400 to be implemented. For example, the user can obtain a list of recommended AV modifications and the user can approve all of the recommendations for implementation by the AV or a subset of the recommended AV modifications. If the user selects a subset of the recommended AV modifications, the user and/or the AV can implement those AV modifications recommended by the process 400 and selected by the user, and decide not to implement those AV modifications recommended by the process 400 but not selected by the user. In some cases, the process 400 can ignore or remove those AV modifications recommended by the process 400 but not selected by the user or can process those recommendations in any other way (e.g., continue to recommend those AV modifications, use those AV recommendations to learn preferences of the user and adjust future recommendations accordingly, deprioritize or assign a lower ranking to those recommendations, etc.).

In some aspects, the process 400 can include receiving use case data, and simulating the performance of the one or more AV modifications further based on the use case data. In some examples, the use case data can include a history of trips performed by one or more autonomous vehicles, a history of simulated trips associated with one or more autonomous vehicles, a history derived entirely or at least partially from a real history of trips, one or more metrics collected from one or more trips performed by one or more autonomous vehicles, and/or one or more second collected from one or more simulated autonomous vehicle trips.

In some aspects, the process 400 can include determining a set of AV modifications estimated to have an impact on the one or more objectives when implemented by the autonomous vehicle. In some cases, the set of AV modifications can include the one or more AV modifications.

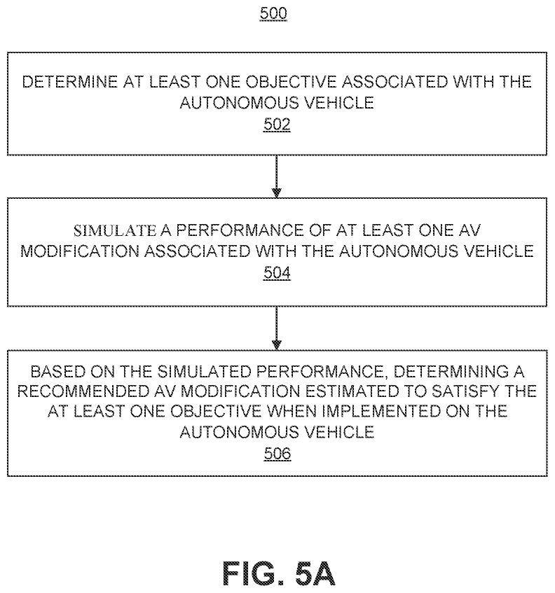

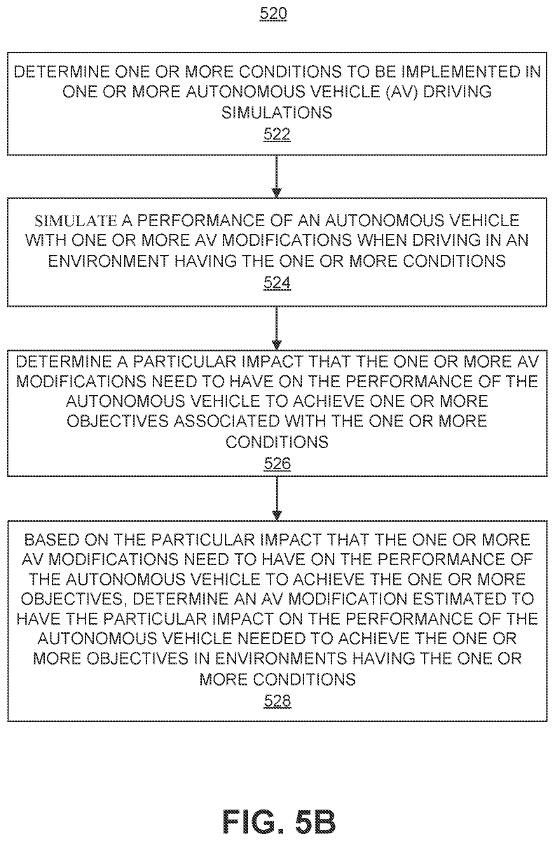

FIG. 5A is a flowchart illustrating an example process 500 for simulating input objectives to determine one or more AV modifications that can allow an autonomous vehicle (e.g., AV 102) to meet an input objective. At block 502, the process 500 can include determining at least one objective associated with the autonomous vehicle.

In some examples, the at least one objective can include an increased number of trips that the autonomous vehicle can complete within a period of time, a decreased amount of time the autonomous vehicle takes to complete one or more trips, an increased amount of items that the autonomous vehicle can deliver, an increased number of people that the autonomous vehicle can transport within a period of time, an increased battery performance or efficiency, and/or an increased revenue from one or more paid trips by the autonomous vehicle. In some cases, the at least one objective can also include one or more constraints. The one or more constraints can include, for example and without limitation, a weather constraint/condition, an environment constraint/condition, a traffic constraint/condition, a road constraint/condition, a legal or regulatory condition, and/or an event in the environment.

At block 504, the process 500 can include simulating a performance of at least one AV modification associated with the autonomous vehicle. In some examples, the at least one AV modification can include a modification or replacement of a software of the autonomous vehicle, a hardware component of the autonomous vehicle, a mechanical system of the autonomous vehicle, a part of the autonomous vehicle, a vehicle model associated with the autonomous vehicle, a cabin of the autonomous vehicle, and/or a container used by the autonomous vehicle to transport one or more items.

At block 506, the process 500 can include determining, based on the simulated performance, a recommended AV modification estimated to satisfy the at least one objective when implemented on the autonomous vehicle. For example, the process 500 can determine an AV modification(s) that can be implemented on the autonomous vehicle in order to satisfy the at least one objective.

FIG. 5B is a flowchart illustrating an example process 520 for determining AV modifications that would satisfy one or more input objectives. At block 522, the process 520 can include determining one or more conditions to be implemented in one or more autonomous vehicle (AV) driving simulations. The one or more conditions can include, for example and without limitation, a weather condition, an environment condition, a traffic condition, a road condition, a legal or regulatory condition, and/or an event in the environment.

At block 524, the process 520 can include simulating a performance of an autonomous vehicle (e.g., AV 102) with one or more AV modifications when driving in an environment having the one or more conditions. In some examples, the one or more AV modifications can include a modification or replacement of a software of the autonomous vehicle, a hardware component of the autonomous vehicle, a mechanical system of the autonomous vehicle, a part of the autonomous vehicle, a vehicle model associated with the autonomous vehicle, a cabin of the autonomous vehicle, and/or a container used by the autonomous vehicle to transport one or more items.

At block 526, the process 520 can include determining a particular impact that the one or more AV modifications need to have on the performance of the autonomous vehicle to achieve one or more objectives associated with the one or more conditions. For example, if the one or more conditions include a threshold amount of fog in an environment, the one or more AV modifications include an upgrade of sensors used to perceive events and objects in fog conditions, and the one or more objectives include increasing the number of trips completed in environments having the threshold amount of fog, the process 520 can include determining how much of an improvement in the sensors ability to perceive events and objects in fog conditions would be needed to allow the autonomous vehicle to travel faster in environments with the threshold amount of fog (e.g., because of the improved perception abilities in fog environments) in order to increase the number of trips completed in environments having the threshold amount of fog and thus satisfy the one or more objectives.

In some examples, the one or more objectives can include an increased number of trips that the autonomous vehicle can complete within a period of time under the one or more simulation conditions, a decreased amount of time the autonomous vehicle takes to complete one or more trips under the one or more simulation conditions, an increased amount of items that the autonomous vehicle can deliver under the one or more simulation conditions, an increased number of people that the autonomous vehicle can transport within a period of time and under the one or more simulation conditions, an increased battery performance or efficiency, and/or an increased revenue from one or more paid trips by the autonomous vehicle under the one or more simulation conditions.

At block 528, the process 520 can include determining, based on the particular impact that the one or more AV modifications need to have on the performance of the autonomous vehicle to achieve the one or more objectives, an AV modification estimated to have the particular impact on the performance of the autonomous vehicle needed to achieve the one or more objectives in environments having the one or more conditions. In some examples, the AV modification can include a modification or replacement of a software of the autonomous vehicle, a hardware component of the autonomous vehicle, a mechanical system of the autonomous vehicle, a part of the autonomous vehicle, a vehicle model associated with the autonomous vehicle, a cabin of the autonomous vehicle, and/or a container used by the autonomous vehicle to transport one or more items.

In some aspects, the process 520 can include receiving use case data; and simulating the performance of the autonomous vehicle with the one or more AV modifications further based on the use case data. The use case data can include, for example, a history of trips performed by one or more autonomous vehicles, a history of simulated trips associated with one or more autonomous vehicles, a history derived entirely or at least partially from a real history of trips, one or more first metrics collected from one or more trips performed by one or more autonomous vehicles, and/or one or more second metrics collected from one or more simulated autonomous vehicle trips.

In some examples, determining the particular impact can include determining an improvement to one or more functionalities of the autonomous vehicle needed to achieve the one or more objectives. The improvement to the one or more functionalities can include, for example, an increased accuracy of an object detection functionality in environments having the one or more conditions, an increase in a sensing or perception functionality of the autonomous vehicle in environments having the one or more conditions, an increased visibility in environments having the one or more conditions, an increase in an energy efficiency of the autonomous vehicle when driving in environments having the one or more conditions, and/or an improvement in one or more navigation capabilities in environments having the one or more conditions.

In some aspects, the process 520 can include determining, based on the simulated performance of the autonomous vehicle with the one or more AV modifications, how the one or more AV modifications impact the one or more objectives when implemented to drive in the environment having the one or more conditions.

FIG. 6 illustrates an example processor-based system with which some aspects of the subject technology can be implemented. For example, processor-based system 600 can be any computing device making up local computing device 110, client computing device 170, a passenger device executing the ridesharing application 172, or any component thereof in which the components of the system are in communication with each other using connection 605. Connection 605 can be a physical connection via a bus, or a direct connection into processor 610, such as in a chipset architecture. Connection 605 can also be a virtual connection, networked connection, or logical connection.

In some examples, computing system 600 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example system 600 includes at least one processing unit (CPU or processor) 610 and connection 605 that couples various system components including system memory 615, such as read-only memory (ROM) 620 and random-access memory (RAM) 625 to processor 610. Computing system 600 can include a cache of high-speed memory 612 connected directly with, in close proximity to, and/or integrated as part of processor 610.

Processor 610 can include any general-purpose processor and a hardware service or software service, such as services 632, 634, and 636 stored in storage device 630, configured to control processor 610 as well as a special-purpose processor where software instructions are incorporated into the actual processor design. Processor 610 may essentially be a completely self-contained computing system, containing multiple cores or processors, a bus, memory controller, cache, etc. A multi-core processor may be symmetric or asymmetric.

To enable user interaction, computing system 600 can include an input device 645, which can represent any number of input mechanisms, such as a microphone for speech, a touch-sensitive screen for gesture or graphical input, keyboard, mouse, motion input, speech, etc. Computing system 600 can also include output device 635, which can be one or more of a number of output mechanisms known to those of skill in the art. In some instances, multimodal systems can enable a user to provide multiple types of input/output to communicate with computing system 600. Computing system 600 can include communications interface 640, which can generally govern and manage the user input and system output. The communication interface may perform or facilitate receipt and/or transmission wired or wireless communications via wired and/or wireless transceivers, including those making use of an audio jack/plug, a microphone jack/plug, a universal serial bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/9G/LTE cellular data network wireless signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof.

Communications interface 640 may also include one or more Global Navigation Satellite System (GNSS) receivers or transceivers that are used to determine a location of the computing system 600 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 630 can be a non-volatile and/or non-transitory computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (L1/L2/L3/L4/L9/L #), resistive random-access memory (RRAM/ReRAM), phase change memory (PCM), spin transfer torque RAM (STT-RAM), another memory chip or cartridge, and/or a combination thereof.

Storage device 630 can include software services, servers, virtual machines, software containers, applications, etc., which, when the code of such software services, servers, virtual machines, software containers, applications, etc., is executed by the processor 610, causes the system to perform a function. In some examples, a hardware service that performs a particular function can include the software component stored in a computer-readable medium in connection with the necessary hardware components, such as processor 610, connection 605, output device 635, etc., to carry out the function.

As understood by those of skill in the art, machine-learning techniques can vary depending on the desired implementation. For example, machine-learning schemes can utilize one or more of the following, alone or in combination: hidden Markov models; recurrent neural networks; convolutional neural networks (CNNs); deep learning; Bayesian symbolic methods; general adversarial networks (GANs); support vector machines; image registration methods; applicable rule-based system. Where regression algorithms are used, they may include including but are not limited to: a Stochastic Gradient Descent Regressor, and/or a Passive Aggressive Regressor, etc.

Machine learning classification models can also be based on clustering algorithms (e.g., a Mini-batch K-means clustering algorithm), a recommendation algorithm (e.g., a Miniwise Hashing algorithm, or Euclidean Locality-Sensitive Hashing (LSH) algorithm), and/or an anomaly detection algorithm, such as a Local outlier factor. Additionally, machine-learning models can employ a dimensionality reduction approach, such as, one or more of: a Mini-batch Dictionary Learning algorithm, an Incremental Principal Component Analysis (PCA) algorithm, a Latent Dirichlet Allocation algorithm, and/or a Mini-batch K-means algorithm, etc.

Aspects within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special-purpose computer, or special-purpose processing device to perform a certain function or group of functions. By way of example, computer-executable instructions can be used to implement perception system functionality for determining when sensor cleaning operations are needed or should begin. Computer-executable instructions can also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other examples of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Aspects of the disclosure may also be practiced in distributed computing environments where tasks are performed by local and remote processing devices that are linked (either by hardwired links, wireless links, or by a combination thereof) through a communications network. In a distributed computing environment, program modules can be located in both local and remote memory storage devices.

The various examples described above are provided by way of illustration only and should not be construed to limit the scope of the disclosure. For example, the principles herein apply equally to optimization as well as general improvements. Various modifications and changes may be made to the principles described herein without following the example aspects and applications illustrated and described herein, and without departing from the spirit and scope of the disclosure.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

Illustrative examples of the disclosure include:

Aspect 1. A system comprising: a memory; and one or more processors coupled to the memory, the one or more processors being configured to: determine one or more simulation conditions to be implemented in one or more autonomous vehicle (AV) driving simulations; simulate a performance of one or more AV modifications when implemented by an autonomous vehicle to drive in an environment having the one or more simulation conditions; and based on the simulated performance of the one or more AV modifications, determine an impact of the one or more AV modifications on one or more objectives associated with the autonomous vehicle.

Aspect 2. The system of Aspect 1, wherein the one or more AV modifications comprise a modification or replacement of at least one of a software of the autonomous vehicle, a hardware component of the autonomous vehicle, a mechanical system of the autonomous vehicle, a part of the autonomous vehicle, a vehicle model associated with the autonomous vehicle, a cabin of the autonomous vehicle, and a container used by the autonomous vehicle to transport one or more items.

Aspect 3. The system of Aspect 1 or 2, wherein the one or more simulation conditions comprise at least one of a weather condition, an environment condition, a traffic condition, a road condition, a legal and/or regulatory condition, and an event in the environment.

Aspect 4. The system of any of Aspects 1 to 3, wherein the one or more processors are configured to: receive use case data; and simulate the performance of the one or more AV modifications further based on the use case data.

Aspect 5. The system of Aspect 4, wherein the use case data comprises at least one of a history of trips performed by one or more autonomous vehicles, a history of simulated trips associated with one or more autonomous vehicles, a history derived entirely or at least partially from a real history of trips, one or more first metrics collected from one or more trips performed by one or more autonomous vehicles, and one or more second metrics collected from one or more simulated autonomous vehicle trips.

Aspect 6. The system of any of Aspects 1 to 5, wherein the one or more processors are configured to determine a set of AV modifications estimated to have an impact on the one or more objectives when implemented by the autonomous vehicle, wherein the set of AV modifications comprises the one or more AV modifications.

Aspect 7. The system of any of Aspects 1 to 6, wherein the one or more objectives comprise at least one of an increased number of trips that the autonomous vehicle can complete within a period of time under the one or more simulation conditions, a decreased amount of time the autonomous vehicle takes to complete one or more trips under the one or more simulation conditions, an increased amount of items that the autonomous vehicle can deliver under the one or more simulation conditions, an increased number of people that the autonomous vehicle can transport within a period of time and under the one or more simulation conditions, an increased battery performance or efficiency, and an increased revenue from one or more paid trips by the autonomous vehicle under the one or more simulation conditions.

Aspect 8. The system of any of Aspects 1 to 7, wherein the one or more processors are configured to: determine at least one objective associated with the autonomous vehicle; simulate a performance of at least one AV modification associated with the autonomous vehicle; and based on the simulated performance, determine a recommended AV modification estimated to satisfy the at least one objective when implemented on the autonomous vehicle.

Aspect 9. A method comprising: determining one or more simulation conditions to be implemented in one or more autonomous vehicle (AV) driving simulations; simulating a performance of one or more AV modifications when implemented by an autonomous vehicle to drive in an environment having the one or more simulation conditions; and based on the simulated performance of the one or more AV modifications, determining an impact of the one or more AV modifications on one or more objectives associated with the autonomous vehicle.

Aspect 10. The method of Aspect 9, wherein the one or more AV modifications comprise a modification or replacement of at least one of a software of the autonomous vehicle, a hardware component of the autonomous vehicle, a mechanical system of the autonomous vehicle, a part of the autonomous vehicle, a vehicle model associated with the autonomous vehicle, a cabin of the autonomous vehicle, and a container used by the autonomous vehicle to transport one or more items.

Aspect 11. The method of Aspect 9 or 10, wherein the one or more simulation conditions comprise at least one of a weather condition, an environment condition, a traffic condition, a road condition, a legal and/or regulatory condition, and an event in the environment.

Aspect 12. The method of any of Aspects 9 to 11, further comprising: receiving use case data; and simulating the performance of the one or more AV modifications further based on the use case data.

Aspect 13. The method of Aspect 12, wherein the use case data comprises a history of at least one of real trips performed by one or more autonomous vehicles, and simulated trips performed by one or more autonomous vehicles.

Aspect 14. The method of Aspect 12 or 13, wherein the use case data comprises at least one of first metrics obtained from one or more real trips performed by one or more vehicles, second metrics obtained from one or more simulated vehicle trips, and statistics derived at least partially from a history of at least one of real vehicle trips and simulated vehicle trips.

Aspect 15. The method of any of Aspects 9 to 14, further comprising determining a set of AV modifications estimated to have an impact on the one or more objectives when implemented by the autonomous vehicle.

Aspect 16. The method of Aspect 15, wherein the set of AV modifications comprises the one or more AV modifications.

Aspect 17. The method of any of Aspects 9 to 16, wherein the one or more objectives comprise at least one of an increased number of trips that the autonomous vehicle can complete within a period of time under the one or more simulation conditions, a decreased amount of time the autonomous vehicle takes to complete one or more trips under the one or more simulation conditions, an increased amount of items that the autonomous vehicle can deliver under the one or more simulation conditions, an increased number of people that the autonomous vehicle can transport within a period of time and under the one or more simulation conditions, an increased battery performance or efficiency, and an increased revenue from one or more paid trips by the autonomous vehicle under the one or more simulation conditions.

Aspect 18. The method of any of Aspects 9 to 17, further comprising: determining at least one objective associated with the autonomous vehicle; simulating a performance of at least one AV modification associated with the autonomous vehicle; and based on the simulated performance, determining a recommended AV modification estimated to satisfy the at least one objective when implemented on the autonomous vehicle.

Aspect 19. The method of Aspect 18, wherein the recommended AV modification comprises at least one of a change in one or more tires of the autonomous vehicle, an addition of one or more sensors and/or types of sensors to the autonomous vehicle, an upgrade of a software and/or a hardware of one or more sensors implemented by the autonomous vehicle, a modification to a cabin of the autonomous vehicle, a modification to a software version of the autonomous vehicle, an implementation of one or more machine learning models (e.g., alternatively or additionally to one or more other machine learning models implemented by the autonomous vehicle), changing or upgrading an operating system implemented by a computer of the autonomous vehicle, a modification of a mechanical system of the autonomous vehicle (e.g., change to a mechanical system (or a component(s) thereof) of the autonomous vehicle, an addition of a mechanical system of the autonomous vehicle (e.g., change to a mechanical system (or a component(s) thereof) of the autonomous vehicle, a removal of a mechanical system of the autonomous vehicle (e.g., change to a mechanical system (or a component(s) thereof) of the autonomous vehicle, etc.), and upgrading and/or modifying software of the autonomous vehicle.

Aspect 20. A non-transitory computer-readable medium having stored thereon instructions which, when executed by one or more processors, cause the one or more processors to perform a method according to any of Aspects 9 to 19.

Aspect 21. A system comprising means for performing a method according to any of Aspects 9 to 19.

Aspect 22. The system of Aspect 21, wherein the system comprises an autonomous vehicle.

Aspect 23. An autonomous vehicle comprising a computer, the computer comprising memory and one or more processors coupled to the memory, the one or more processors being configured to perform a method according to any of Aspects 9 to 19.

Aspect 24. A computer program product comprising instructions which, when executed by one or more processors, cause the one or more processors to perform a method according to any of Aspects 9 to 19.

Aspect 25. A system comprising: a memory; and one or more processors coupled to the memory, the one or more processors being configured to: determine one or more conditions to be implemented in one or more autonomous vehicle (AV) driving simulations; simulate a performance of an autonomous vehicle with one or more AV modifications when driving in an environment having the one or more conditions; determine a particular impact that the one or more AV modifications need to have on the performance of the autonomous vehicle to achieve one or more objectives associated with the one or more conditions; and based on the particular impact that the one or more AV modifications need to have on the performance of the autonomous vehicle to achieve the one or more objectives, determine an AV modification estimated to have the particular impact on the performance of the autonomous vehicle needed to achieve the one or more objectives in environments having the one or more conditions.

Aspect 26. The system of Aspect 25, wherein the AV modification comprises a modification or replacement of at least one of a software of the autonomous vehicle, a hardware component of the autonomous vehicle, a mechanical system of the autonomous vehicle, a part of the autonomous vehicle, a vehicle model associated with the autonomous vehicle, a cabin of the autonomous vehicle, and a container used by the autonomous vehicle to transport one or more items.

Aspect 27. The system of Aspect 25 or 26, wherein the one or more simulation conditions comprise at least one of a weather condition, an environment condition, a traffic condition, a road condition, a legal or regulatory condition, and an event in the environment.

Aspect 28. The system of any of Aspects 25 to 27, wherein the one or more processors are configured to: receive use case data; and simulate the performance of the autonomous vehicle with the one or more AV modifications further based on the use case data.

Aspect 29. The system of Aspect 28, wherein the use case data comprises at least one of a history of trips performed by one or more autonomous vehicles, a history of simulated trips associated with one or more autonomous vehicles, a history derived entirely or at least partially from a real history of trips, one or more first metrics collected from one or more trips performed by one or more autonomous vehicles, and one or more second metrics collected from one or more simulated autonomous vehicle trips.

Aspect 30. The system of any of Aspects 25 to 29, wherein determining the particular impact comprises determining an improvement to one or more functionalities of the autonomous vehicle needed to achieve the one or more objectives, the improvement to the one or more functionalities comprising at least one of an increased accuracy of an object detection functionality in environments having the one or more conditions, an increase in a sensing or perception functionality of the autonomous vehicle in environments having the one or more conditions, an increased visibility in environments having the one or more conditions, an increase in an energy efficiency of the autonomous vehicle when driving in environments having the one or more conditions, and an improvement in one or more navigation capabilities in environments having the one or more conditions.

Aspect 31. The system of any of Aspects 25 to 30, wherein the one or more objectives comprise at least one of an increased number of trips that the autonomous vehicle can complete within a period of time under the one or more conditions, a decreased amount of time the autonomous vehicle takes to complete one or more trips under the one or more conditions, an increased amount of items that the autonomous vehicle can deliver under the one or more conditions, an increased number of people that the autonomous vehicle can transport within a period of time and under the one or more conditions, an increased battery performance or efficiency, and an increased revenue from one or more paid trips by the autonomous vehicle under the one or more conditions.

Aspect 32. The system of any of Aspects 25 to 31, wherein the one or more processors are configured to: determine, based on the simulated performance of the autonomous vehicle with the one or more AV modifications, how the one or more AV modifications impact the one or more objectives when implemented to drive in the environment having the one or more conditions.

Aspect 33. A method comprising: determining one or more conditions to be implemented in one or more autonomous vehicle (AV) driving simulations; simulating a performance of an autonomous vehicle with one or more AV modifications when driving in an environment having the one or more conditions; determining a particular impact that the one or more AV modifications need to have on the performance of the autonomous vehicle to achieve one or more objectives associated with the one or more conditions; and based on the particular impact that the one or more AV modifications need to have on the performance of the autonomous vehicle to achieve the one or more objectives, determining an AV modification estimated to have the particular impact on the performance of the autonomous vehicle needed to achieve the one or more objectives in environments having the one or more conditions.

Aspect 34. The method of Aspect 33, wherein the AV modification comprises a modification or replacement of at least one of a software of the autonomous vehicle, a hardware component of the autonomous vehicle, a mechanical system of the autonomous vehicle, a part of the autonomous vehicle, a vehicle model associated with the autonomous vehicle, a cabin of the autonomous vehicle, and a container used by the autonomous vehicle to transport one or more items.

Aspect 35. The method of Aspect 33 or 34, wherein the one or more conditions comprise at least one of a weather condition, an environment condition, a traffic condition, a road condition, a legal or regulatory condition, and an event in the environment.

Aspect 36. The method of any of Aspects 33 to 35, further comprising: receiving use case data; and simulating the performance of the autonomous vehicle with the one or more AV modifications further based on the use case data.

Aspect 37. The method of Aspect 36, wherein the use case data comprises at least one of a history of trips performed by one or more autonomous vehicles, a history of simulated trips associated with one or more autonomous vehicles, a history derived entirely or at least partially from a real history of trips, one or more first metrics collected from one or more trips performed by one or more autonomous vehicles, and one or more second metrics collected from one or more simulated autonomous vehicle trips.

Aspect 38. The method of any of Aspects 33 to 37, wherein determining the particular impact comprises determining an improvement to one or more functionalities of the autonomous vehicle needed to achieve the one or more objectives, the improvement to the one or more functionalities comprising at least one of an increased accuracy of an object detection functionality in environments having the one or more conditions, an increase in a sensing or perception functionality of the autonomous vehicle in environments having the one or more conditions, an increased visibility in environments having the one or more conditions, an increase in an energy efficiency of the autonomous vehicle when driving in environments having the one or more conditions, and an improvement in one or more navigation capabilities in environments having the one or more conditions.

Aspect 39. The method of any of Aspects 33 to 38, wherein the one or more objectives comprise at least one of an increased number of trips that the autonomous vehicle can complete within a period of time under the one or more simulation conditions, a decreased amount of time the autonomous vehicle takes to complete one or more trips under the one or more simulation conditions, an increased amount of items that the autonomous vehicle can deliver under the one or more simulation conditions, an increased number of people that the autonomous vehicle can transport within a period of time and under the one or more simulation conditions, an increased battery performance or efficiency, and an increased revenue from one or more paid trips by the autonomous vehicle under the one or more simulation conditions.

Aspect 40. The method of any of Aspects 33 to 39, further comprising: determining, based on the simulated performance of the autonomous vehicle with the one or more AV modifications, how the one or more AV modifications impact the one or more objectives when implemented to drive in the environment having the one or more conditions.

Aspect 41. A non-transitory computer-readable medium having stored thereon instructions which, when executed by one or more processors, cause the one or more processors to perform a method according to any of Aspects 33 to 39.

Aspect 42. A system comprising means for performing a method according to any of Aspects 33 to 39.

1. A system comprising:
a memory; and
one or more processors coupled to the memory, the one or more processors being configured to:
determine one or more conditions and a plurality of autonomous vehicle (AV) modifications to be implemented in a plurality of software-based driving simulations;
simulate, via the plurality of software-based driving simulations, an impact of each of the plurality of AV modifications on a performance of an AV when operating in an environment having the one or more conditions;
based on the simulated impact of each of the plurality of the AV modifications on the performance of the AV when operating in the environment having the one or more conditions, determine whether a simulated performance of the AV with any of the plurality of AV modifications satisfies one or more performance objectives in environments having the one or more conditions;
select a particular AV modification from the plurality of AV modifications based on a determination that the simulated performance of the AV with the particular AV modification satisfies the one or more performance objectives; and
configure the AV to implement the particular AV modification.

2. The system of claim 1, wherein the AV modification comprises a modification or replacement of at least one of a sensor of the AV, a sensor software implemented by the AV, and a hardware component of the AV.

3. The system of claim 1, wherein the one or more conditions comprise at least one of a weather condition, an environment condition, a traffic condition, a road condition, a legal or regulatory condition, and an event in the environment.

4. The system of claim 1, wherein the one or more processors are configured to:
determine at least one of a type of performance improvement and an amount of performance improvement predicted to satisfy the one or more performance objectives, wherein the at least one of the type of performance improvement and the amount of performance improvement corresponds to the performance of the AV in environments having the one or more conditions, and wherein determining whether the simulated performance of the AV with any of the plurality of AV modifications satisfies the one or more performance objectives in environments having the one or more conditions is further based on the at least one of the type of performance improvement and the amount of performance improvement.

5. The system of claim 1, wherein the one or more processors are configured to simulate the impact of each of the plurality of AV modifications on the performance of the AV when operating in the environment further based on use case data, the use case data comprising at least one of a history of trips performed by one or more autonomous vehicles, a history of simulated trips associated with one or more autonomous vehicles, a history derived entirely or at least partially from a real history of trips, one or more first metrics collected from one or more trips performed by one or more autonomous vehicles, and one or more second metrics collected from one or more simulated autonomous vehicle trips.

6. The system of claim 1, wherein the one or more processors are configured to determine that a respective performance of the AV without any of the plurality of AV modifications does not satisfy the one or more performance objectives in environments having the one or more conditions, wherein determining whether the simulated performance of the AV with any of the plurality of AV modifications satisfies the one or more performance objectives in environments having the one or more conditions comprises determining an improvement to one or more functionalities of the autonomous vehicle estimated to result in a performance improvement that satisfies the one or more performance objectives in environments having the one or more conditions, the improvement to the one or more functionalities comprising at least one of an increased accuracy of an object detection functionality in environments having the one or more conditions, an increase in a sensing or perception functionality of the autonomous vehicle in environments having the one or more conditions, an increased visibility in environments having the one or more conditions, an increase in an energy efficiency of the autonomous vehicle when driving in environments having the one or more conditions, and an improvement in one or more navigation capabilities in environments having the one or more conditions.

7. The system of claim 1, wherein the one or more objectives comprise at least one of an increased number of trips completed by the AV under the one or more conditions and within a period of time, a decreased amount of time the AV takes to complete one or more trips under the one or more conditions, an increased amount of items that the AV delivers under the one or more conditions, an increased number of people that the AV transports within a period of time and under the one or more conditions, an increased battery performance or efficiency, and an increased revenue from one or more paid trips by the AV under the one or more conditions.

8. The system of claim 1, wherein the one or more processors are configured to: simulating the impact of each of the plurality of AV modifications on the performance of the AV when operating in the environment having the one or more conditions comprises determining at least one of a type of improvement and an amount of improvement of each of the plurality of AV modifications on the performance of the AV when implemented to drive in the environment having the one or more conditions.

9. A method comprising:
determining one or more conditions and a plurality of autonomous vehicle (AV) modifications to be implemented in a plurality of software-based driving simulations;
simulating via the plurality of software-based driving simulations, an impact of each of the plurality of AV modifications on a performance of an AV when operating in an environment having the one or more conditions;
determining a particular based on the simulated impact of each of the plurality of the AV modifications on the performance of the AV when operating in the environment having the one or more conditions, determining whether a simulated performance of the AV with any of the plurality of AV modifications satisfies one or more performance objectives in environments having the one or more conditions;
selecting a particular AV modification from the plurality of AV modifications based on a determination that the simulated performance of the AV with the particular AV modification satisfies the one or more performance objectives; and
configuring the AV to implement the particular AV modification.

10. The method of claim 9, wherein the AV modification comprises a modification or replacement of at least one of a software of the autonomous vehicle, a hardware component of the autonomous vehicle, a mechanical system of the autonomous vehicle, a cabin of the autonomous vehicle, and a container used by the autonomous vehicle to transport one or more items.

11. The method of claim 9, wherein the one or more conditions comprise at least one of a weather condition, an environment condition, a traffic condition, a road condition, a legal or regulatory condition, and an event in the environment.

12. The method of claim 9, further comprising:
receiving use case data; and
simulating the impact of each of the plurality of AV modifications on the performance of the AV further based on the use case data.

13. The method of claim 12, wherein the use case data comprises at least one of a history of trips performed by one or more autonomous vehicles, a history of simulated trips associated with one or more autonomous vehicles, a history derived entirely or at least partially from a real history of trips, one or more first metrics collected from one or more trips performed by one or more autonomous vehicles, and one or more second metrics collected from one or more simulated autonomous vehicle trips.

14. The method of claim 9, further comprising determining that a respective performance of the AV without any of the plurality of AV modifications does not satisfy the one or more performance objectives in environments having the one or more conditions, wherein determining whether the simulated performance of the AV with any of the plurality of AV modifications satisfies the one or more performance objectives in environments having the one or more conditions comprises determining an improvement to one or more functionalities of the autonomous vehicle estimated to result in a performance improvement that satisfies the one or more performance objectives in environments having the one or more conditions, the improvement to the one or more functionalities comprising at least one of an increased accuracy of an object detection functionality in environments having the one or more conditions, an increase in a sensing or perception functionality of the autonomous vehicle in environments having the one or more conditions, an increased visibility in environments having the one or more conditions, an increase in an energy efficiency of the autonomous vehicle when driving in environments having the one or more conditions, and an improvement in one or more navigation capabilities in environments having the one or more conditions.

15. The method of claim 9, wherein the one or more objectives comprise at least one of an increased number of trips completed by the AV under the one or more conditions and within a period of time, a decreased amount of time the AV takes to complete one or more trips under the one or more conditions, an increased amount of items that the AV delivers under the one or more conditions, an increased number of people that the AV transports within a period of time and under the one or more conditions, an increased battery performance or efficiency, and an increased revenue from one or more paid trips by the AV under the one or more conditions.

16. The method of claim 9, wherein simulating the impact of each of the plurality of AV modifications on the performance of the AV when operating in the environment having the one or more conditions comprises determining at least one of a type of improvement and an amount of improvement of each of the plurality of AV modifications on the performance of the AV when implemented to drive in the environment having the one or more conditions.

17. A non-transitory computer-readable medium having stored thereon instructions which, when executed by one or more processors, cause the one or more processors to:
determine one or more conditions and a plurality of autonomous vehicle (AV) modifications to be implemented in a plurality of software-based driving simulations;
simulate, via the plurality of software-based driving simulations, an impact of each of the plurality of AV modifications on a performance of an AV when operating in an environment having the one or more conditions;
based on the simulated impact of each of the plurality of the AV modifications on the performance of the AV when operating in the environment having the one or more conditions, determine whether a simulated performance of the AV with any of the plurality of AV modifications satisfies one or more performance objectives in environments having the one or more conditions;
select a particular AV modification from the plurality of AV modifications based on a determination that the simulated performance of the AV with the particular AV modification satisfies the one or more performance objectives; and
configure the AV to implement the particular AV modification.

18. The non-transitory computer-readable medium of claim 17, wherein the AV modification comprises a modification or replacement of at least one of a sensor of the AV and a sensor software implemented by the AV.

19. The non-transitory computer-readable medium of claim 17, wherein the one or more conditions comprise at least one of a weather condition, an environment condition, a traffic condition, a road condition, a legal or regulator condition, and an event in the environment.

20. The non-transitory computer-readable medium of claim 17, wherein the one or more objectives comprise at least one of an increased number of trips completed by the AV under the one or more conditions and within a period of time, a decreased amount of time the AV takes to complete one or more trips under the one or more conditions, an increased amount of items that the AV delivers under the one or more conditions, an increased number of people that the AV transports within a period of time and under the one or more conditions, an increased battery performance or efficiency, and an increased revenue from one or more paid trips by the AV under the one or more conditions.
